(19) United States
(12) Patent Application Publication
(10) Pub. No.: US 2025/0227949 A1
(43) Pub. Date: Jul. 10, 2025

(54) HETEROSTRUCTURES WITH NANOSTRUCTURES OF LAYERED MATERIAL

(71) Applicants: The Regents of the University of Michigan, Ann Arbor, MI (US); Ohio State Innovation Foundation, Columbus, OH (US)

(72) Inventors: Ping Wang, Ann Arbor, MI (US); Woncheol Lee, Ann Arbor, MI (US); Joseph P. Corbett, Springfield, OH (US); Ding Wang, Ann Arbor, MI (US); Jay A. Gupta, Columbus, OH (US); Emmanouil Kioupakis, Dexter, MI (US); Zetian Mi, Ann Arbor, MI (US)

(21) Appl. No.: 18/852,921

(22) PCT Filed: Mar. 30, 2023
(86) PCT No.: PCT/US2023/016826

§ 371 Date: Sep. 30, 2024

Related U.S. Application Data
(60) Provisional application No. 63/325,236, filed on Mar. 30, 2022.

(51) Int. Cl. H10D 30/47; C30B 25/04; C30B 25/18; C30B 29/40; C30B 29/68

(52) U.S. Cl. CPC H10D 30/481; C30B 25/04; C30B 25/18; C30B 29/403; C30B 29/68

(57) ABSTRACT

A method of fabricating a heterostructure includes forming a layered material structure such that the layered material structure has an edge, and growing epitaxially a nanostructure of layered material laterally from the edge of the layered material structure such that an inplane interface between the layered material structure and the nanostructure is defined. Growing the nanostructure is implemented at a growth temperature sufficiently near a decomposition temperature of the layered material such that a nucleation interface of the nanostructure has a single atomic configuration.

### CROSS-REFERENCE TO RELATED APPLICATION

This application claims the benefit of U.S. provisional application entitled “Heterostructures with Nanostructures of Layered Material,” filed Mar. 30, 2022, and assigned Ser. No. 63/325,236, the entire disclosure of which is hereby expressly incorporated by reference.

### STATEMENT REGARDING FEDERALLY SPONSORED RESEARCH OR DEVELOPMENT

This invention was made with government support under Contract No. W911NF-17-1-0312 awarded by the U.S. Army Research Office and under Contracts Nos. 1807984 and 2118809 awarded by the National Science Foundation. The government has certain rights in the invention.

### BACKGROUND OF THE DISCLOSURE

### Field of the Disclosure

The disclosure relates generally to heterostructures.

### Brief Description of Related Technology

The emerging two-dimensional (2D) materials and their heterostructures have provided exciting prospects for the applications of next-generation electronic, photonic, and quantum devices. Monolayer hexagonal boron nitride (hBN) and graphene (G), the thinnest of all insulators and semimetals, respectively, have been considered as fundamental building blocks of such 2D devices. Specifically, vertically stacked hBN/graphene (hBN/G) van der Waals (vdW) heterostructures have been successfully employed to produce emergent properties, such as quantum Hall effect, Hofstadter butterfly spectrum, and plasmon and phonon polaritons. Complementary to the vertical hBN/G vdW heterostructure, the in-plane version forms a covalent hBN/G heterostructure with useful properties, such as transitions between semiconducting, half-metallic, and metallic phases, spin polarization magnetism, and exotic electronic states, or the possibility to reconstruct electronic interfaces similar to those observed in oxide heterostructures.

Efforts have been devoted to the epitaxial growth of hBN on metals, sapphire, and graphene substrates by using sputtering, chemical vapor deposition (CVD), metal-organic chemical vapor deposition (MOCVD), and molecular beam epitaxy (MBE). Due to the compatible lattice symmetry and small lattice mismatch (around 1.6%), highly oriented pyrolytic graphite (HOPG) and epitaxial graphene have emerged as promising substrates for the epitaxy of monolayer hBN as well as hBN/G heterostructures. In addition, the moiré superlattice formed between epitaxially grown hBN/G heterostructures can be utilized to engineer correlated quantum electronic states in vdW heterostructures. However, the epitaxy of hBN/G heterostructures with controlled interface configuration has remained elusive. In addition, the recent experimentally measured 6.1 eV emission energy for monolayer hBN on graphene differs greatly from the theoretically predicted 8 eV bandgap for freestanding monolayer hBN.

### SUMMARY OF THE DISCLOSURE

In accordance with one aspect of the disclosure, a method of fabricating a heterostructure, includes forming a layered material structure such that the layered material structure has an edge, and growing epitaxially a nanostructure of layered material laterally from the edge of the layered material structure such that an in-plane interface between the layered material structure and the nanostructure is defined. Growing the nanostructure is implemented at a growth temperature sufficiently near a decomposition temperature of the layered material such that a nucleation interface of the nanostructure has a single atomic configuration.

In accordance with another aspect of the disclosure, a device includes a substrate, and a heterostructure supported by the substrate. The heterostructure includes a layered material structure supported by the substrate, and a nanostructure disposed laterally adjacent to the layered material structure to define an interface between the layered material structure and the nanostructure, the nanostructure including a layered material. An edge of the nanostructure opposite the interface has a single atomic configuration.

In accordance with yet another aspect of the disclosure, a device includes a substrate, and a heterostructure supported by the substrate. The heterostructure includes a layered material structure supported by the substrate, and a nanostructure disposed laterally adjacent to the layered material structure to define an interface between the layered material structure and the nanostructure, the nanostructure including a layered material. An edge of the nanostructure opposite the interface has a single atomic configuration. The substrate includes a layered material surface. The nanostructure is disposed on, and is in contact with, the layered material surface of the substrate to form a moiré superlattice.

In accordance with still yet another aspect of the disclosure, a device includes a substrate, and a heterostructure supported by the substrate. The heterostructure includes a layered material structure supported by the substrate, and a nanostructure disposed laterally adjacent to the layered material structure to define an interface between the layered material structure and the nanostructure, the nanostructure including a layered material. An edge of the nanostructure opposite the interface has a single atomic configuration. The substrate includes a surface of metal or semi-metal. The nanostructure includes hexagonal boron nitride. The nanostructure is disposed on, and is in contact with, the surface to form a stacked heterostructure. The stacked heterostructure has a bandgap lower than a bandgap of hexagonal boron nitride.

In accordance with still yet another aspect of the disclosure, a device includes a substrate, and a heterostructure supported by the substrate. The heterostructure includes a layered material structure supported by the substrate, and a nanostructure disposed laterally adjacent to the layered material structure to define an interface between the layered material structure and the nanostructure, the nanostructure including a layered material. An edge of the nanostructure opposite the interface has a single atomic configuration. The substrate includes a graphene surface. The nanostructure includes hexagonal boron nitride. The nanostructure is disposed on, and is in contact with, the graphene surface to form a stacked heterostructure. The stacked heterostructure exhibits photoluminescence.

In connection with any one of the aforementioned aspects, the devices and/or methods described herein may alternatively or additionally include or involve any combination of one or more of the following aspects or features. The growth temperature is closer to the decomposition temperature than to a threshold temperature at which growth of the layered material occurs. The layered material includes hexagonal boron nitride. The growth temperature is at or above 1600 degrees Celsius. The layered material includes hexagonal boron nitride, the layered material structure includes graphene. Growing the nanostructure includes growing a monolayer of the layered material. The single atomic configuration is an armchair||armchair atomic configuration. The single atomic configuration establishes that a growth front of the nanostructure is unidirectional. The layered material structure includes graphene. Forming the layered material structure includes exfoliating a substrate that supports the layered material structure to define the layered material structure and the unidirectional atomic edge. Forming the layered material structure includes depositing layered material across a substrate such that the layered material is supported by the substrate, and patterning the deposited layered material to define the layered material structure. The method further includes providing a substrate that supports the layered material structure, the substrate including graphite. Forming the layered material structure includes implementing a photolithography procedure to define the unidirectional atomic edge. Growing the nanostructure includes growing a nanoribbon of the layered material. Forming the layered material structure includes forming a plurality of defects in a surface of the layered material structure. The single atomic configuration establishes that the edge is unidirectional. The interface has an armchair||armchair atomic configuration. The nanostructure is a monolayer of the layered material. The layered material includes hexagonal boron nitride. The layered material structure includes graphene. The substrate includes an insulating material. The device further includes a drain electrode, a source electrode spaced from the drain electrode, and a gate electrode disposed between the drain and source electrodes. The nanostructure is disposed between the gate electrode and the layered material structure to act as a gate dielectric of a lateral transistor arrangement. The layered material structure is disposed between the drain and source electrodes in accordance with the lateral transistor arrangement. The device further includes a drain electrode, a source electrode spaced from the drain electrode, and a gate electrode disposed between the drain and source electrodes. The heterostructure further includes a semiconductor layer on which the nanostructure is disposed, and an insulator layer on which the semiconductor layer is disposed. The nanostructure is disposed in a stacked arrangement between the gate electrode and the semiconductor layer to act as a dielectric layer for the gate electrode. The device further includes a heterostructure stack including first and second structures spaced apart by the nanostructure. The nanostructure includes a nanoribbon.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts a schematic views of heterostructures having monolayer hBN grown along the armchair (AC_{G}) and zigzag (ZZ_{G}) graphene atomic edges in accordance with several examples, as well as scanning electron microscope (SEM) images of straight and jagged monolayer hBN nanoribbons, as well as a graphical plot of measured percentage of straight versus jagged hBN nanoribbons and nanoribbon density as a function of growth temperature.

FIG. 2 depicts scanning tunneling microscopy (STM) images of a straight monolayer hBN nanoribbon in accordance with one example, the nanoribbon exhibiting a Moiré superlattice with a single periodicity spanning the entire monolayer hBN region, as well as the corresponding fast Fourier transforms (FFTs).

FIG. 3 depicts a schematic view of a photoluminescence (PL) experiment performed on one of the monolayer hBN/HOPG heterostructures of FIG. 1 (part g), as well as a graphical plot of measured, time—integrated PL spectra and reflectance spectra, as well as a graphical plot of the temperature dependence of normalized PL-peak intensity.

FIG. 4 depicts a graphical plot of a quasiparticle band structure of a freestanding monolayer hBN example and an example heterostructure of monolayer hBN on three graphene layers, as well as a graphical plot of calculated direct bandgap of monolayer hBN for a varying number of graphene layers, as well as a graphical plot of a calculated absorption spectrum of a freestanding monolayer hBN and monolayer hBN on three graphene layers, as well as a spatial map of the exciton wavefunction for the 1s-exciton state of monolayer hBN on three graphene layers.

FIG. 5 depicts SEM and STM images of an example of hBN/graphene interface-mediated growth and the corresponding uniform moiré superlattice, respectively, as well as a schematic view of the corresponding van der Waals heterostructure.

FIG. 6 is a flow diagram of a method of fabricating a heterostructure having a nanostructure of layered material in accordance with one example.

FIG. 7 is a schematic plan and side views of a transistor device having a stacked heterostructure with a nanostructure of layered material in accordance with one example.

FIG. 8 is a schematic plan and views of an electronic device having a heterostructure with a nanostructure of layered material in accordance with one example.

FIG. 9 depicts schematic plan and side views of a transistor device having a lateral heterostructure with a nanostructure of layered material in accordance with one example.

FIG. 10 depicts schematic plan and side views of a light emitting device having a heterostructure with a nanostructure of layered material in accordance with one example

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Methods of fabricating heterostructures in which a nanostructure of layered material is grown at a growth temperature sufficiently high to control a nucleation interface of the nanostructure are described. The growth temperature may be sufficiently high such that only the most stable nucleation interface survives. As a result, the nucleation interface exhibits a single atomic configuration, such as an armchair-armchair atomic configuration. The nanostructure may thus have a unidirectional atomic boundary or edge. In some cases, the disclosed methods are directed to growing a nanostructure composed of hexagonal boron nitride. Devices having such heterostructures are also described.

In some cases, the disclosed devices and methods include or involve interface-mediated synthesis of monolayer hBN nanoribbons or other nanostructures on graphene and controlled synthesis of the corresponding 2D monolayer heterostructures. The synthesis is scalable. For instance, the nanoribbons or other nanostructures of hBN may be synthesized on a wafer-scale.

The term “nanostructure” is used herein to include structures of a variety of shapes. The nanostructures may or may not be elongated in the form of, for instance, nanoribbons. The term is also used with the understanding that one or more dimensions (e.g., length or width) of the structure may be larger than nanoscale, but nonetheless constitute a nanostructure due to the nanoscale thickness of the structure.

The disclosed devices may exhibit bandgap renormalization. In heterostructures examples including hBN and graphene, giant bandgap renormalization may be achieved. Theoretical calculations predict a giant bandgap renormalization, 0.7 eV exciton binding energy, and excitonic emission at 6.21 eV for monolayer hBN on graphene, which matches deep-ultraviolet (UV) photoluminescence (PL) measured emissions at 6.12 eV.

A number of material and device properties (e.g., transitions between semiconducting, half-metallic, and metallic phases, spin polarization magnetism, exotic electronic states, and electronic interfaces) may be expanded via epitaxially grown monolayer hBN on graphene with superior structural, electrical, and optical properties, as well as a precise control of both the hBN/G out-of-plane and in-plane monolayer interfaces.

Described herein are examples involving an interface-mediated growth mechanism for the controlled epitaxy of monolayer hBN on graphene with superior structural, electrical, and optical properties. By implementing this approach, unidirectional, lateral epitaxy of monolayer hBN has been achieved by controlling the energetically stable in-plane hBN/G interface formation. A Moiré superlattice spanning the entire monolayer hBN with single periodicity indicates lattice registry between hBN and underlying graphene without apparent rotation. An experiment-theory comparison identifies that the deep—UV emission at 6.12 eV originates from the 1s—exciton state of monolayer hBN with a giant renormalized direct bandgap on graphene. The disclosed devices and methods accordingly provide a framework for the controllable epitaxy of monolayer hBN on graphene substrates and other 2D materials, offering a useful approach for the precise construction of both in-plane and out-of-plane monolayer heterointerfaces and heterostructures.

Although described in connection with light emitting and/or optoelectronic devices, the disclosed methods and devices may be applied to a wide variety of electronic and other devices. For instance, the disclosed devices may be configured for quantum computing and other electronic functions and applications.

Although described in connection with examples having 2D heterostructures, the disclosed devices and methods may include or involve heterostructures of varying construction, configuration, and composition. For instance, the disclosed methods and devices may include or involve any number of additional layers, structures, or elements, including, for instance, III-nitride structures (e.g., GaN, InN, AIN, and their alloys), other III-V structures, or other semiconductor structures.

The compositions of other elements or components of the disclosed devices may also vary. For instance, the disclosed devices are not limited to a particular substrate material or a particular type of layered material. While the disclosed devices and methods are described in connection with graphite substrates, other substrate materials may be used, including, for instance, graphene. While the disclosed devices and methods are described in connection with hBN monolayers, other layered materials may be used, including, for instance, Molybdenum disulfide (MoS₂), Molybdenum diselenide (MoSe₂), Tungsten disulfide (WS₂), Tungsten diselenide (WSe₂), and graphene.

The substrate of the disclosed devices may or may not correspond with the growth substrate, or the substrate on which the heterostructures of the disclosed devices are grown. For instance, the heterostructures may be transferred to another substrate, such as a GaN, Si, or sapphire substrate, after growth of the heterostructures.

The substrate may or may not have a composition in common with a layered material of the heterostructure. For instance, the substrate may be composed of, or otherwise include, graphene, GaN, AlN, or their alloys, sapphire, and SiC, while the layered material may be composed of, or otherwise include, graphene, MoS₂, WS₂, or WSe₂.

The configuration, construction, fabrication, and other characteristics of the heterostructures may also vary from the examples described. For instance, the heterostructures may include any number of epitaxially grown layers.

Although described in connection with MBE growth procedures, additional or alternative non-sputtered epitaxial growth procedures may be used. For instance, out-of-organic chemical vapor deposition (MOCVD) and hydride vapor phase epitaxy (HVPE) growth procedures may be used. Still other procedures may be used, including, for instance, pulsed laser deposition procedures.

In the examples described below, heterostructures were fabricated by controlling a growth interface (e.g., hBN/G interface formation) to create uniform active sites that promote precise nucleation (e.g., hBN nucleation) and eventually faultless, in-plane lateral epitaxy. The epitaxial growth may continue up to macroscopic scales. Unless controlled, graphene substrates unintentionally contain arbitrary mixtures of so-called armchair (AC) and zigzag (ZZ) atomic edges. This leads to a myriad of possible hBN/G in-plane interfaces.

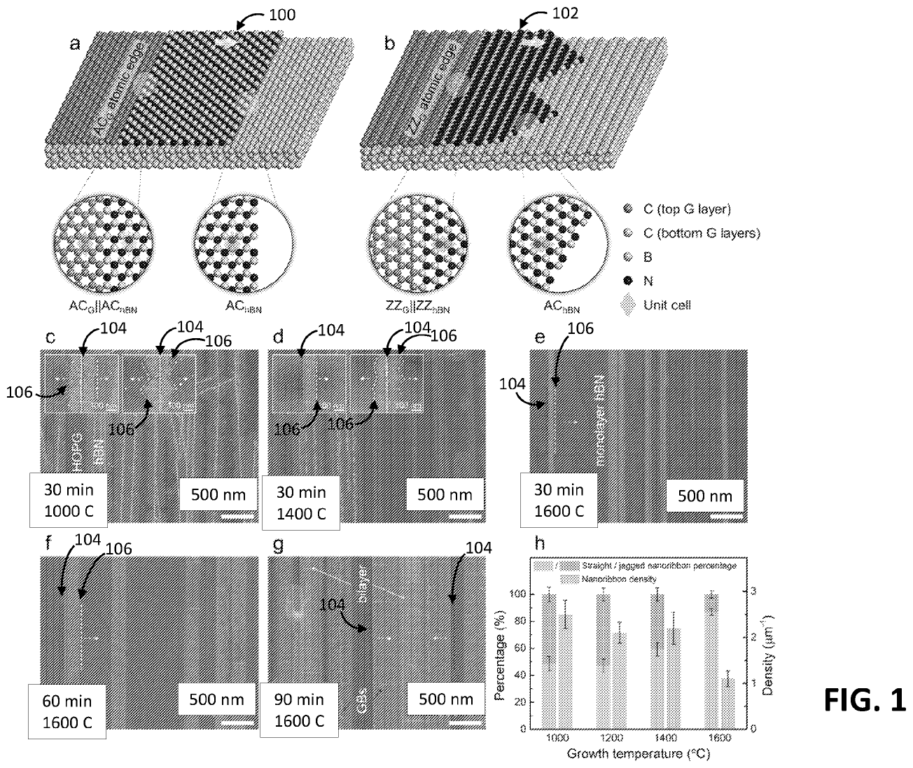

FIG. 1, part a, shows an example of interface-mediated synthesis of monolayer hBN. Parts a and b depict schematic views of monolayer hBN grown along the a) armchair (AC_{G}) and b) zigzag (ZZ_{G}) graphene atomic edges, forming straight and jagged nanoribbons 100, 102, respectively. All growth fronts of monolayer hBN are terminated with AC_{hBN} edges. Magnifications show the atomic configurations of the AC_{G}||AC_{hBN} and ZZ_{G}||ZZ_{hBN} in-plane interfaces, and the AC_{hBN} growth fronts. White arrows indicate the growth direction. Parts c-e of FIG. 1 depict SEM images of monolayer hBN nanoribbons morphology, grown along graphene atomic edges at c) 1000° C., d) 1400° C., and e) 1600° C. for 30 min. Insets in parts c and d show the typical morphology of the straight and jagged hBN nanoribbons 100, 102. Parts e-g of FIG. 1 depict examples of the evolution of straight monolayer hBN nanoribbons followed after e) 30 min, f) 60 min, and g) 90 min growth time at 1600° C. Red dashed lines 104 depict hBN/graphene nucleation interfaces and white dashed lines 106 show the outline of hBN growth fronts; white dashed arrows point to the growth direction. White solid arrows indicate bilayer hBN formed from the initial hBN/graphene nucleation interfaces after underlying straight monolayer hBN nanoribbons coalescence; red solid arrows show the grain boundaries (GBs) formed during nanoribbon growth and coalescence. Part h of FIG. 1 shows measured percentage of straight versus jagged hBN nanoribbons and nanoribbon density as a function of growth temperature, demonstrating the dominance of straight nanoribbons (with well-defined AC_{G}||AC_{hBN} in-plane interfaces) at a growth temperature of 1600° C. The error bar is the standard deviation.

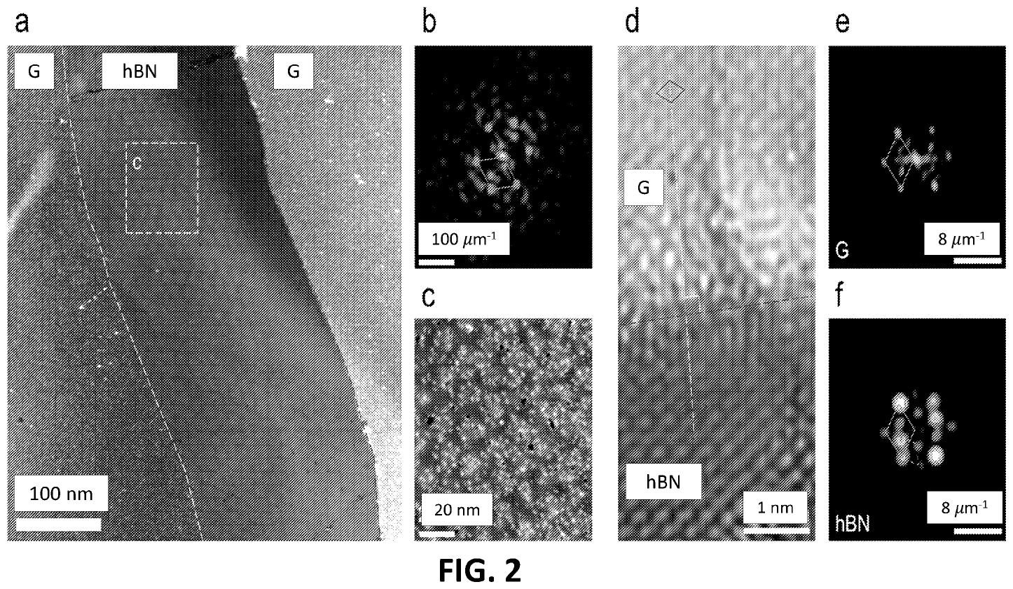

FIG. 2, part a, shows an example of the epitaxial registry between monolayer hBN and graphene. Parts a-c of FIG. 2 depict an example of a Moiré superlattice with a single periodicity spanning the entire monolayer hBN region. Specifically, part a is an STM image of a straight monolayer hBN nanoribbon (grown at 1600° C. for 60 min, FIG. 1, part f), showing a clear moiré superlattice. Part b is the corresponding FFT, showing a hexagonal lattice. Part c shows a magnified image of the white box in part a. The red dashed and white dashed lines in part a depict the hBN/G nucleation interface and the outline of hBN growth front, respectively, and the white dashed arrow shows the growth direction. The green and red diamonds in parts b and c represent the unit cell of a moiré superlattice in reciprocal-space and real-space, respectively. Parts d-f of FIG. 1 show the nucleation interface atomic configuration for straight monolayer hBN nanoribbons. Specifically, part d is an atomic-resolved STM image acquired from a straight monolayer hBN nanoribbon nucleation interface. Parts e and f are the corresponding FFTs for the graphene and hBN regions, respectively. The red solid and green solid (dashed) diamonds represent the corresponding unit (super) cell in real- and reciprocal-space, respectively. The red dashed line in part d indicates the hBN/G nucleation interface, while the yellow dashed line shows the alignment of unit cells. They are perpendicular to each other. The AC_{G}||AC_{hBN} interface configuration is unambiguously confirmed by comparing the experimentally measured unit cell alignment with the atomic model shown in FIG. 1, part a.

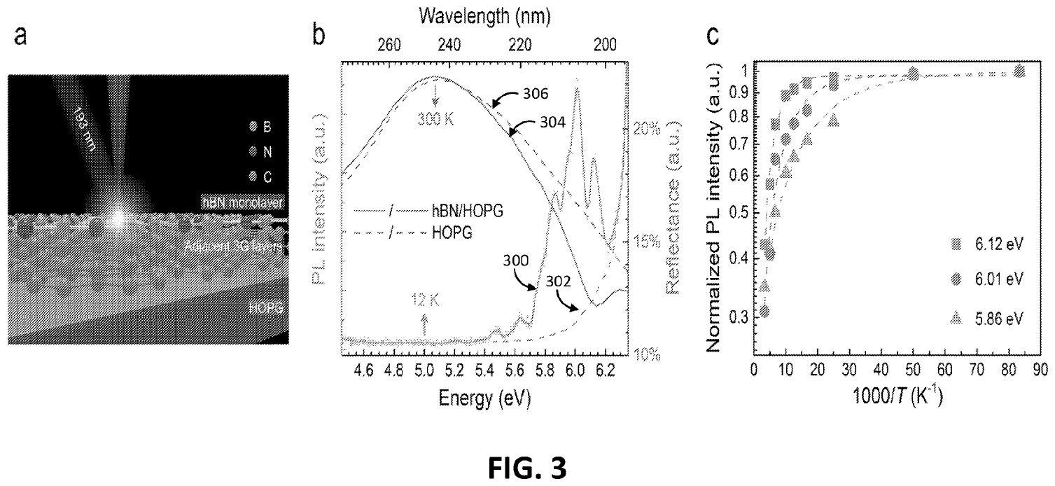

FIG. 3 schematically shows an example epitaxial monolayer hBN in deep-UV emission. Part a of FIG. 3 is a schematic view of the photoluminescence experiment performed on monolayer hBN/HOPG heterostructure of FIG. 1, part g. Part b of FIG. 3 shows the measured, time-integrated PL spectra 300, 302 (blue curves, 12 K) and reflectance spectra 304, 306 (red curves, 300 K) of monolayer hBN/HOPG heterostructure (solid curves) and HOPG substrate (dashed curves). The gray circles are the photoluminescence raw data for monolayer hBN/HOPG heterostructures, while the blue solid curve is the corresponding smoothed curve. Part c of FIG. 3 shows the temperature dependence of PL-peak intensity normalized to its T=12 K value for the hBN/HOPG heterostructure.

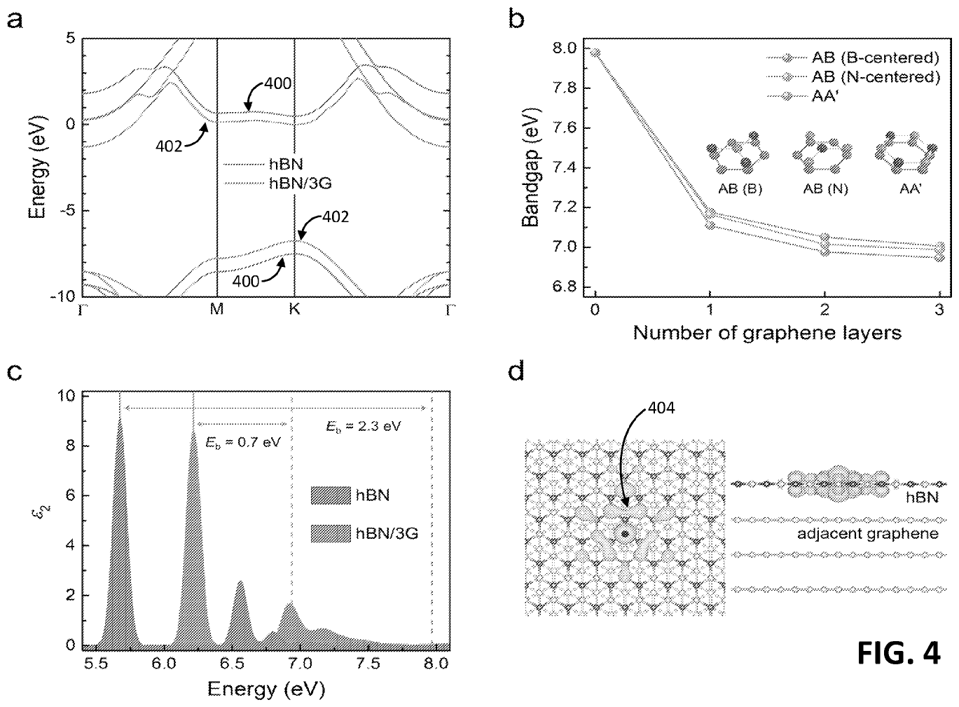

FIG. 4, part a, shows an example of giant bandgap renormalization of monolayer hBN on graphene. Part a depicts a quasiparticle band structure of freestanding monolayer hBN 400 (gray curves) and monolayer hBN on three graphene layers 402 (hBN/3G, blue curves). Part b depicts a calculated direct bandgap of monolayer hBN for a varying number of graphene layers. Insets show the three different stacking configurations used for the vertical hBN/G interface. Part c shows a calculated absorption spectrum of a freestanding monolayer hBN (gray area) and monolayer hBN on three graphene layers (blue area). The vertical dashed lines indicate the quasiparticle bandgap, and the vertical solid lines show the 1s-exciton state position. Part d is a spatial map of the exciton wavefunction for the 1s-exciton state of monolayer hBN on three graphene layers: along the in-plane direction (left) and along the out-of-plane direction (right). The hole 404 (red dot) is fixed slightly below a nitrogen atom. The isosurface is set to be 3% of the maximum isovalue. The electron and hole distributions are well confined within the monolayer hBN region.

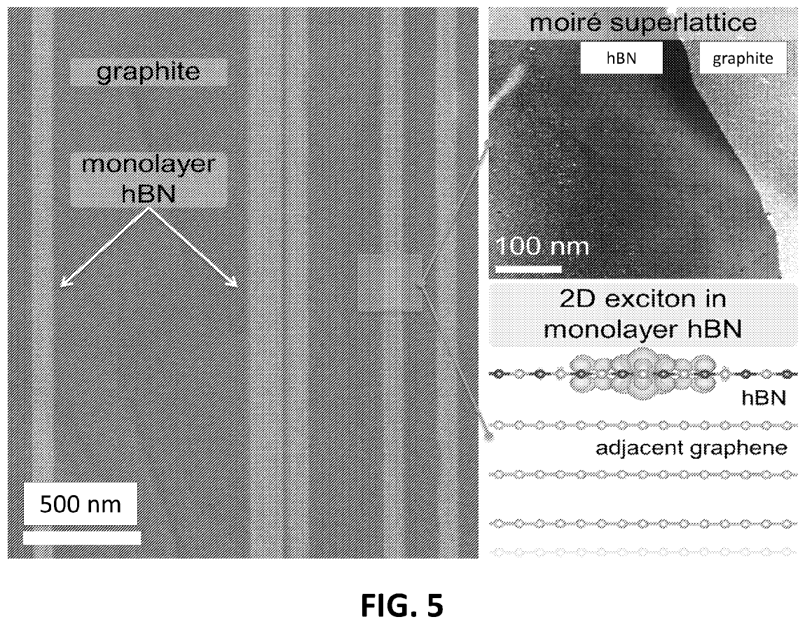

FIG. 5 shows an example of controllable synthesis of monolayer hBN. The synthesis is achieved via hBN/graphene interface-mediated growth, which, in turn, enables scalable epitaxy of unidirectional high-quality monolayer hBN (e.g., on graphite substrates). Uniform moiré superlattice and robust deep-ultraviolet excitonic emission (around 6.12 eV) are achieved in such monolayer hBN/graphene van der Waals heterostructure as described further herein.

Further details regarding the subject matter of FIGS. 1-5 are provided below.

FIG. 1, part a, shows an AC_{G}||AC_{hBN} interface and FIG. 1, part b, shows an ZZ_{G}||ZZ_{hBN} interface, which are the two most likely edge configurations due to the relatively low formation energy. Uncontrolled interfaces have so far prevented precise and flexible synthesis of hBN/G heterostructures. The coexistence of these interfaces also makes the unidirectional hBN single-domain formation and controllable coalescence elusive. Theoretical calculations have suggested a smaller formation energy for the AC_{G}||AC_{hBN} interface (2.2 eV/nm) compared to the ZZ_{G}||ZZ_{hBN} interface (2.8 eV/nm), indicating that the AC_{G}||AC_{hBN} interface is energetically more stable than the ZZ_{G}||ZZ_{hBN} interface, when grown under nearly thermal equilibrium conditions, such as ultrahigh growth temperatures. This difference may be used to control the atomic configuration of the hBN/G interface. Based on the thermodynamic stability of the hBN/G interfaces, an interface-mediated synthesis technique is used for MBE-grown hBN on graphene substrates. The technique suppresses the formation of a ZZ_{G}||ZZ_{hBN} interface. Heterostructures (e.g., hBN/G heterostructures) are fabricated under nearly thermal equilibrium conditions to grow exclusively AC_{G}||AC_{hBN} interfaces, which makes unidirectional, superior quality hBN lateral epitaxy possible.

The ultrahigh growth temperature achieves the selective formation of the nucleation interface. On the graphite substrate, both armchair and zigzag edges may coexist on the surface. Under ultrahigh growth temperature conditions, only the AC||AC interface is stable, while the metastable ZZ||ZZ interface will not form. Therefore, unidirectional growth of the hBN nanoribbon 100 from the AC||AC nucleation interface is achieved.

Under optimal conditions, a pristine hBN front grows along a single direction, in a single pattern, and from a single graphene atomic edge. The intermediate product is then an hBN nanoribbon extending to present a pristine monolayer hBN (e.g., once its width becomes macroscopic). To control the actual growth conditions, monolayer hBN has been synthesized on HOPG substrates using MBE at growth temperatures ranging from 800 to 1600° C.

FIG. 1, parts c-e, show scanning electron microscopy (SEM) images characterizing the hBN growth. The light areas denote hBN, while the dark areas denote HOPG. Red dashed lines 104 denote the hBN/graphene nucleation interfaces, and white dashed lines 106 denote the hBN growth fronts whose propagation direction is indicated by white dashed arrows. For the growth temperature of 1000° C., nanoribbons start to grow in both directions from the opposite graphene atomic edges. Moreover, different regions produce randomly either straight or jagged hBN nanoribbons, as shown by exemplary regions in the inset of FIG. 1, part c. Similarly imperfect growth behavior was observed for 1200° C.

The growth mode starts to drastically change at about 1400° C., producing unidirectional growth from the graphene atomic edge to produce a uniform, ultraclean, and straight hBN nanoribbon as shown in FIG. 1, part d, although, in this case, some regions still show bidirectional growth. At about 1600° C., unidirectional growth dominates essentially all regions as shown in FIG. 1, part e. In this example, each of the straight nanoribbons are monolayer hBN with a thickness of about 0.35 nm, a uniform width, and length up to sub-millimeter scale. The evolution of the hBN nanoribbons with growth duration is shown in FIG. 1, parts e-g. Nanoribbon width increases linearly with a 3 nm/min lateral growth rate. This can be exploited to grow macroscopic monolayer hBN if the graphene substrate (or other structure supported by the substrate) includes, for instance, a single graphene atomic edge. However, in this example, the HOPG substrate (or other structure supported by the substrate) includes multiple graphene atomic edges (e.g., a high density of graphene atomic edges) on the surface, producing terraces separated by hundreds of nanometers. Therefore, extending the growth time to 90 min still produces straight hBN nanoribbons, but seamlessly stitched with the adjacent ones to eventually form large area monolayer hBN as seen in FIG. 1, part g. In this case, due to the nonuniform height (monolayer to multiple layers) of graphene atomic edges on HOPG, a new monolayer hBN started to grow on top of the coalesced hBN along the initial graphene atomic edge, forming bilayer regions, as indicated by white solid arrows in FIG. 1, part g. In addition, the nonuniform graphene atomic edges may also introduce grain boundaries (GBs) during the growth of the nanoribbons and coalescence (FIG. 1, part g). By utilizing graphene substrates (or structures supported by a substrate) with well-isolated or spaced apart atomic edges, the disclosed growth technique offers a viable path to achieve ultraclean, wafer-scale monolayer hBN and hBN/G heterostructures.

Nonideal growth temperatures (in this case, equal to or below 1200° C.) often produce bidirectional lateral hBN growth, which is attributed to the formation of BN nanoparticles (see, e.g., the bright dots in the SEM images in FIG. 1, parts c and d, along the graphene atomic edges). At lower growth temperatures, boron adatoms tend to accumulate along the graphene edges due to large diffusion length on graphene and relatively low desorption rate. During growth, with the irradiation of nitrogen plasma, those boron clusters are converted into BN nanoparticles. The nanoparticles enable both in-plane and out-of-plane hBN/G interface formation.

In contrast, higher growth temperatures dramatically suppress the formation of BN nanoparticles, allowing only the energetically stable in-plane hBN/G interface to survive. As a result, the hBN monolayer grows only on the in-plane side of graphene for the 1600° C. growth. In addition, the active nitrogen plasma may introduce defects in graphene. Such defects have been experimentally confirmed in previous graphene-assisted III-nitride growth. However, no negative impact of such defects was observed on hBN nucleation and growth, which is likely due to the limited (point) defect size.

High-temperature annealing has been proposed as an effective approach to improve the crystallinity of hBN and the crystal quality of AlN. High-temperature annealing was performed at 1600° C. in the same MBE chamber for the hBN samples grown at lower temperatures. However, the morphology of hBN nanoribbons as well as the above mentioned BN nanoparticles barely changed, which is attributed to the robust thermal stability of BN.

The quality of the temperature-dependent hBN growth is quantified in FIG. 1, part h, in terms of straight and jagged nanoribbon fraction as well as nanoribbon density. At growth temperatures below 1200° C., straight and jagged hBN nanoribbons have almost the same percentage, 50%. As the growth temperature is increased to about 1600° C., the percentage of straight hBN nanoribbon significantly increases up to 87% and the nanoribbon density decreases almost to half compared to lower growth temperatures. This results from the suppressed growth of jagged hBN nanoribbons. In other words, a highly selective growth of uniform, ultraclean, and straight hBN nanoribbons has been demonstrated by utilizing ultrahigh growth temperatures, close to the thermal equilibrium conditions. Notably, 100% selectivity may be achievable by further increasing the growth temperature. In this case, the growth temperature was limited by the safe operating temperature of the MBE system. In other cases with other MBE systems or other growth systems, higher growth temperatures may be used.

To further quantify the quality of the hBN monolayers, scanning tunneling microscopy (STM) was used to image the monolayer hBN grown at 1600° C. for 60 min, corresponding to FIG. 1, part f, where straight nanoribbons have not yet coalesced into the complete monolayer hBN film.

Additionally, to improve the coverage of hBN on the surface of the graphene, a high density of nucleation sites may be introduced on the graphene surface. In some cases, the introduction of the nucleation sites may be achieved by performing a relatively long duration (e.g., beyond 1 hour) in situ nitrogen-plasma irradiation, leading to the formation of a high density of uniform point defects on the graphene terrace. These point defects have a similar function as the graphene step edges. For instance, the point defects provide a number of dangling bonds on the graphene surface. Therefore, hBN can nucleate and laterally grow on top of the graphene surface, forming hBN hexagonal islands. Due to the same epitaxial registry with the underlying graphene, the hBN islands are capable of easily coalescing with each other, and thus may finally form a continuous monolayer of hBN.

In one example, four hBN structures were grown at 1000, 1200, 1400, and 1600° C. on graphene substrates with a nitrogen-plasma treatment having a duration of 1 hour. Full coverage was achieved at growth temperatures below about 1200° C. The aforementioned graphene edge induced lateral epitaxy remains dominant for the hBN structures grown at higher growth temperatures (e.g., greater than or equal to about 1400° C.), indicating that the interface modulated epitaxy described herein is also applicable to the growth of hBN on defective graphene structures.

FIG. 2, part a, shows a STM image focused on a single nanoribbon. At this magnification, a uniform moiré superlattice is observed along the entire imaged length of the nanoribbon. The corresponding fast Fourier transform (FFT) (FIG. 2, part b) shows a slightly distorted hexagonal reciprocal lattice, with an average spot separation corresponding to a periodicity of 16 nm. While the visibility of a moiré superlattice varies with the STM tip termination, periodicities of 16±1 nm are observed on nanoribbons in distinct areas of the example. The measured moiré periodicity exceeds the maximum period of 14 nm (FIG. 2, part c), calculated using the bulk hBN lattice constant and rotational alignment with graphene. The larger observed moiré period suggests that the monolayer hBN lattice is compressively strained to be more commensurate with the underlying graphene lattice. Based on these measurements of the moiré superlattice, bounds can be placed on the strain (greater than 0.2%) and twist angle (less than) 0.9°. The slight compressive strain mainly arises from the in-plane covalent hBN/G heterostructure, and the small lattice mismatch (1.6%) between hBN and graphene. These results corroborate the proposed growth model, and are consistent with nearly commensurate, single-domain hBN, aligned to the underlying graphene lattice.

To explore the interface-mediated epitaxy, FIG. 2, part d, presents atomically resolved STM images close the nucleation interface (red dashed line) and growth front regions of the straight monolayer hBN nanoribbons. In FIG. 2, part d, the parent graphene appears on the top of the image, with the hBN nanoribbon growing down toward the bottom. Though the two surfaces are nearly co-planar, the insulating hBN leads to darker contrast, leading to an apparent step down of 260 pm. Atomic-scale contrast at the interface likely reflects defect states associated with hBN/G bonding, which makes it difficult to identify how the two honeycomb lattices are joined. However, the corresponding unit cells in real-space (red diamonds) and reciprocal-space (green diamonds) for the two regions show hexagonal periodicities that are aligned between graphene and hBN, as seen in FIG. 2, parts e and f. This demonstrates that hBN registers to the graphene atomic edge during the initial nucleation, consistent with the AC_{G}||AC_{hBN} interface shown in FIG. 1, part a. Atomic-resolution STM images of the hBN growth front exhibited similar alignment, consistent with growth aligned to the underlying graphene lattice. These results indicate that the produced or survived straight monolayer hBN nanoribbons, when grown under ultrahigh temperatures, are initiating from the AC_{G}||AC_{hBN} interface, agreeing well with the disclosed interface-mediated process.

In addition to confirming the high-quality and single-domain nature of the monolayer hBN, the electrical and optical properties of the monolayer hBN has also been characterized. The monolayer hBN was found to exhibit excellent insulating properties and electrical reliability via conductive atomic force microscopy (cAFM).

The monolayer hBN also exhibited deep UV emissions. The optical properties of monolayer hBN result from extraordinary strong light-matter interaction. Therefore, the hBN/HOPG examples were further characterized by using temperature-variable PL spectroscopy, as schematically shown in FIG. 3, part a. The measured, time-integrated PL spectrum at 12 K (blue curve) and the reflectance spectrum at 300 K (red curve) are presented in FIG. 3, part b, for the monolayer hBN example of FIG. 1, part g. The dashed lines are the reference PL and reflectance spectra of a HOPG substrate alone. Evidently, the epitaxial hBN significantly affects the reflectance spectrum of HOPG in the high photon-energy range, with a pronounced dip at 6.12 eV compared to the monotonic decline of the HOPG substrate reflectance beyond 5.1 eV. This significant extinction of reflected light is indicative of a strong light-matter coupling with the presence of hBN. The pronounced hBN resonance is further corroborated by the PL spectra. Only the hBN/HOPG sample exhibits a sharp resonance at 6.12 eV (FIG. 3, part b). This behavior changes dramatically for the lower-quality samples grown below 1600° C. Those samples produce a broad defect-related emission below 5.6 eV. In contrast, the highest-quality example completely suppresses the defect emission. Specifically, three prominent peaks at 6.12, 6.01, and 5.86 eV were observed and superimposed with a tail of HOPG PL, two of them originating from high-quality monolayer hBN, as discussed below.

To identify the physical origin of these three peaks, the time-integrated PL was measured as function of temperature T. The normalized peak values was constructed with respect to 12 K PL for each peak. FIG. 3, part c, summarizes the temperature T dependence of normalized PL peak intensity for the 6.12 eV (squares), 6.01 eV (circles), and 5.86 eV (triangles) peaks. The 6.12 eV peak intensity drops slightly until T=100 K, and the 6.01 eV peak decreases slowly until T=40 K, whereas the 5.86 eV peak starts to rapidly drop already above 20 K. Both the peak position and T dependence intensity trend for 5.86 eV peak are similar to that observed in multilayer hBN. Thus, the 5.86 eV peak is assigned to multilayer hBN. At the same time, the 6.12 eV PL peak matches with a strong reflection resonance. In fact, it is the only one visible there, indicating it has by far the strongest light-matter coupling. Thus, that peak is assigned to a monolayer hBN whose strongest confinement increases the light-matter coupling much beyond those of multilayers. The presence of both monolayer and multilayer hBN PL resonances is to be expected in the example of FIG. 1, part g, which included multiple layer thicknesses. The temperature dependence of the 6.01 eV peak is between multilayer and monolayer, which indicates it could be from defect-brightened emission in monolayer hBN. This relationship is verified in connection with FIG. 4.

Theoretical calculations and analyses are now presented for the monolayer hBN.

In multilayers hBN with an indirect bandgap, all of the previously reported emissions had a peak energy lower than the indirect exciton (5.96 eV). Recently, the emissions with higher peak energies (above 5.96 eV) were attributed to the carrier transition and recombination processes in monolayer hBN with direct bandgap. However, there is a large difference between the experimentally measured emission (6-6.15 eV) and the theoretically predicted bandgap (8 eV) for a monolayer hBN. To explain the 6.12 eV emission resonance from a monolayer hBN/HOPG heterostructure, first-principles calculations based on density functional theory (DFT) and many-body perturbation theory were used. The substrate-screening method is adopted to reflect the strong screening from the adjacent graphene layers underlying the monolayer hBN.

The computed band structure is presented in FIG. 4, part a, for a freestanding monolayer hBN (gray curves) versus monolayer hBN on three graphene layers (hBN/3G, blue curves). From this band structure, the quasiparticle bandgap E_{g} of monolayer hBN on zero to three graphene layers is constructed. The result is presented in FIG. 4, part b. The zero graphene layer corresponds to the freestanding monolayer hBN, producing a direct E_{g}=7.98 eV at k=K, in agreement with previous reports. Adding graphene layers results in a giant bandgap renormalization of almost 1 eV for all simulated stacking configurations. Indeed, only two graphene layers converges the bandgap within 0.1 eV, which implies extreme screening of the Coulomb interaction by the graphene. Thus, this giant bandgap renormalization is attributed to the metallic character of the graphene layers, which has also been observed for other materials, such as MoS₂ and WSe₂. This trend illustrates that the screening depends only on the adjacent graphene layers as previously reported for other vdW heterostructures. These assessments also agree well with the E_{g}=6.8±0.2 eV recently measured with STM for monolayer hBN, and the variation of the bandgap among different stacking configurations is small, less than 0.1 eV.

To explain the optical spectra and excitonic properties, the Bethe-Salpeter equation including substrate-screening effects is solved. FIG. 4, part c, shows the computed absorption spectrum for a monolayer hBN on three graphene layers (blue area) versus a freestanding monolayer hBN (gray area). The hBN/3G calculation produces a strong 1s-exciton resonance at 6.21 eV, close to the 6.12 eV peak of the measured PL spectrum (FIG. 3, part b). The small difference (0.09 eV) between these energies is attributed to the zero-point energy renormalization, which is expected to be around 0.2 eV for bulk and freestanding monolayer hBN. By comparing the exciton energy to the quasiparticle bandgap, a 0.7 eV exciton binding energy for hBN/3G is obtained, which matches the 0.7 eV binding energy of bulk hBN and is much smaller than the 2.3 eV binding energy for freestanding monolayer hBN. This huge reduction in binding energy also results from the metallic screening by the graphene layers.

FIG. 4, part d, shows the 2D excitonic nature of the 6.21 eV-exciton resonance by examining the exciton wavefunction. The 2D character of the monolayer hBN is very clear because the wavefunction is strongly confined within the monolayer hBN. This result confirms the strong light-matter interactions associated with the measured 6.12 eV reflection and PL resonance (matching 6.21 eV of the computations herein) based on the analysis in FIG. 3. Thus, the measured reflection and emission peak at 6.12 eV indeed stems from the 1s-exciton state of monolayer hBN. This resonance is also distinguished clearly from the PL peaks of multilayer hBN, which are below 5.96 eV. Furthermore, the calculated singlet-triplet splitting energy is 90 meV, similar to the value of bulk hBN and also close to the splitting between the 6.12 and 6.01 eV peaks. This further supports that the PL signal at 6.01 eV is due to defect-induced triplet brightening. Both the phonon replicas of monolayer hBN exciton and trion emissions and the phonon-assisted indirect exciton emissions of multilayers hBN may contribute to the adjacent shoulders of the PL peak at 5.86 eV (FIG. 3, part b).

Described above are examples of methods and devices involving or including hexagonal boron nitride (hBN) and/or other layered materials as a component of two-dimensional (2D) heterostructures and devices. The disclosed methods support the controlled and scalable synthesis of hBN and its 2D heterostructures. The disclosed methods provide a hBN/graphene (hBN/G) interface-mediated growth process for the controlled synthesis of a high-quality monolayer of hBN. The in-plane hBN/G interface can be precisely controlled, enabling the scalable epitaxy of one or more unidirectional hBN monolayers on, e.g., graphene or graphite, which exhibits a uniform moiré superlattice consistent with single-domain hBN, aligned to the underlying graphene lattice. Furthermore, observed deep-ultraviolet emission at 6.12 eV stems from the 1s-exciton state of monolayer hBN with a giant renormalized direct bandgap on graphene. The disclosed devices and methods may accordingly involve or include the controlled synthesis of ultraclean, wafer-scale, atomically ordered 2D quantum materials, as well as the fabrication of 2D quantum electronic and optoelectronic devices.

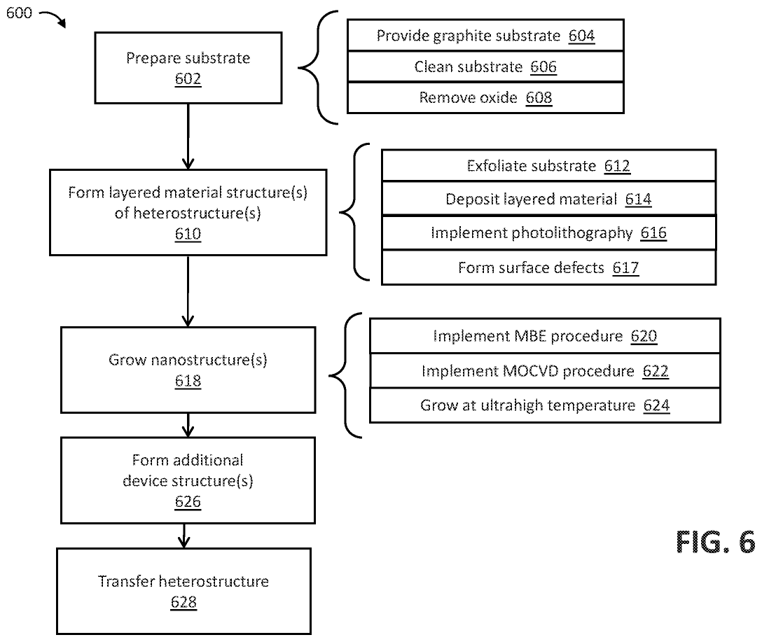

FIG. 6 depicts a method 600 of fabricating a heterostructure having a nanoribbon or other nanostructure of layered material in accordance with one example. As described herein, the method 600 may be configured such that a nucleation interface of the nanostructure has a single atomic configuration. The heterostructure may form a device, or a part of a device, such as a light emitting or other optoelectronic device. In other cases, the device is configured as a transistor or other electronic device. The method 600 may be used to fabricate the device examples described herein, as well as other heterostructures and devices.

The method 600 may begin with an act 602 in which a substrate (e.g., growth substrate) is prepared and/or otherwise provided. In some cases, the act 602 includes providing a graphite substrate in an act 604. For instance, the substrate may be composed of, or otherwise include, HOPG. In the examples described above, a 1×1 cm² HOPG substrate with a mosaic spread of 0.8±0.2° was used as substrate. Alternative or additional materials may be used, including, for instance, graphene. The substrate may thus have a layered material surface (e.g., a graphene surface). The surface may include a metal material or semi-metal other than graphene. Still growth substrates may be used, including, for instance, graphene grown on SiC, sapphire, AIN, SiO2, or other layered or 2D materials grown on still other substrates.

The substrate may be cleaned in an act 606. For instance, the substrate may be cleaned via dips in acetone, methanol, and DI water. Organic impurities may thus be removed. In some cases, a native or other oxide layer may be removed from a substrate surface in an act 608. Additional or alternative processing may be implemented in other cases, including, for instance, baking, degassing (e.g., via thermal degassing), doping or deposition procedures. The substrate thus may or may not have a uniform composition. The substrate may be a uniform or composite structure.

Any one or more of these and/or other cleaning procedures may be implemented later in the method 600, including, for instance, after formation of one or more layered material structures. For instance, in one example, the cleaning procedures are implemented after a fresh surface (e.g., edge growth surface) was obtained by exfoliating the top surface of a HOPG substrate using adhesive tape. After exfoliation, the HOPG substrates were cleaned by acetone, methanol, and DI water. Before growth of the nanoribbon, the HOPG substrates were baked and degassed at 200° C. and 600° C. in a MBE load-lock chamber and preparation chamber for 2 hours, respectively, to obtain a clean surface. The parameters and/or other aspects of these cleaning procedures may vary in other examples, including, for instance, examples involving other types of layered material structures.

In an act 610, a layered material structure is formed. The layered material structure may be formed in a manner such that the layered material structure has a unidirectional atomic edge. For instance, the layered material structure may be composed of, or otherwise include, graphene. In some cases, the layered material structure is formed from the substrate (or a portion of the substrate). For instance, the graphene or other layered material structure and the unidirectional atomic edge thereof may be formed via exfoliation of the substrate in an act 612. In the examples described above, the top surface of a HOPG substrate was exfoliated using adhesive tape. The tape may be configured (e.g., with a straight edge) and applied in a manner that define the unidirectional atomic edge.

Alternatively or additionally, the act 610 includes an act 614 in which layered material is deposited or grown on or across the substrate. The manner in which the layered material is deposited or grown may vary (e.g., in accordance with the composition or other characteristics of the layered material structure). In some cases, the layered material may then be patterned in an act 616 in which a photolithography procedure is implemented to define the unidirectional atomic edge.

In some cases, a number of defects are formed in a top or upper surface of the layered material in an act 617. The defects may be or include point defects. The defects may be formed by performing an in-situ nitrogen plasma irradiation procedure. Additional or alternative procedures may be used. The presence of the defects may support or promote the growth of hBN on the surface for further hBN coverage of the layered material, as described herein.

The layered material structure may include any number of monolayers. As a layered material, adjacent monolayers are bonded to one another via van der Waals forces. In some cases, the monolayers are epitaxially grown in a growth chamber. The monolayers are thus formed on, or otherwise supported by, the substrate. In some cases, one of the monolayers is in contact with the substrate. In other cases, an intermediary layer is disposed between the layered material structure and the substrate. For instance, an insulator may be disposed between the layered material structure and the substrate.

The layered material structure may be formed in still other ways. For instance, one or more monolayers of the layered material structure may be epitaxially grown.

The layered material structure may be composed of, or otherwise include, graphene. Alternative or additional layered or two-dimensional (2D) materials may be used. For instance, the layered material structure may be composed of, or otherwise include, MoS₂. Still other layered materials may be used, including, for instance, MoSe₂, GaSe, InSe, black phosphorus. The layered material structure and the substrate may or may not have a chemical composition in common.

The method 600 includes an act 618 in which one or more nanoribbons of the heterostructure are epitaxially grown. Each nanoribbon is composed of, or otherwise includes, a layered material. The nanoribbon may include a single monolayer of the layered material or multiple monolayers. In some cases, the nanoribbon(s) grown in the act 618 are composed of, or otherwise includes, hBN, but alternative or additional layered materials may be used, including, for instance, graphene, MoS2, MoSe2, GaSe, InSe, black phosphorus.

In some cases, the act 618 includes implementation of a plasma-assisted MBE procedure in an act 620. For instance, the nanoribbon grown in the act 618 (and/or other growth acts described herein) may use a Veeco GENxplor MBE system, equipped with a radio frequency (RF) nitrogen plasma source for active nitrogen supply (N*). Alternative or additional procedures may be implemented, including, for instance, a MOCVD procedure in an act 622.

As described above, the epitaxial growth of the nanoribbon is implemented at a growth temperature sufficiently near a decomposition temperature of the layered material such that only the most stable nucleation interface survives. As a result, a single and uniform atomic configuration is realized. For instance, the growth temperature may be closer to the decomposition temperature than to a threshold temperature at which the growth of the layered material occurs. For example, growth of the layered hBN may begin at about 1000 degrees Celsius, but the growth temperature is closer to the decomposition temperature than 1000 degrees Celsius. In some cases (e.g., hBN examples), the epitaxial growth is implemented at an ultrahigh temperature in an act 624. For example, the growth temperature may be at or above 1600 degrees Celsius. Other high temperature regimes may be used, e.g., in connection with other layered materials.

Use of a growth temperature near the decomposition temperature of the layered material leads to growth near the thermal equilibrium point.

Growth near the decomposition temperature or thermal equilibrium point allows the highest crystalline quality and most stable heterointerface to be obtained. In growth near the decomposition temperature, only the most stable interface (e.g., hBN/graphene interface) survives. The growth temperature is sufficiently high so as to selectively form the most stable interface. In the hBN examples described herein, the most stable interface corresponds to the AC_{G}||AC_{hBN} interface that induces unidirectional growth of the layered (2D) material. Generally, the higher the growth temperature the lower the possibility for forming metastable interfaces, such as the ZZ_{G}||ZZ_{hBN} interface.

The most stable interface thus leads to a single atomic configuration for the nucleation interface of the layered material. As described herein, the single atomic configuration may be an armchair||armchair atomic (AC||AC) configuration rather than a zigzag atomic configuration. The single atomic configuration may thus establish that a unidirectional growth front and, thus, a straight nanoribbon.

Other high growth temperatures may be used to control the interface to a single atomic configuration. For instance, growing the hBN nanoribbon may be implemented at a temperature falling in a range from about 1600 degrees Celsius to about 1800 degrees Celsius. In another example, growing a MoS₂ nanoribbon may be implemented at a temperature falling in a range from about 600 degrees Celsius to about 800 degrees Celsius.

The decomposition temperature of hBN in an ultrahigh vacuum is around 1800 degrees Celsius. The decomposition and other temperature levels addressed herein are accordingly relevant to typical epitaxial growth conditions for the layered material being grown. The growth conditions may, for instance, include or involve a vacuum, an ultrahigh vacuum, a near vacuum, etc., as appropriate. The growth temperatures referenced herein may correspond with a temperature measured by a thermocouple of the substrate heater.

In the examples described above, the hBN nanoribbons were grown using a Veeco GENxplor ultrahigh temperature MBE system equipped with a radio-frequency (RF) plasma-assisted nitrogen source. An integrated Telemark electron beam evaporator was used for boron (B). The growth conditions included a nitrogen flow rate of 2.0 standard cubic centimeters per minute (sccm), RF forward power of 350 W, and a B deposition rate of 0.01 Å/s. The growth conditions may vary from the example, e.g., in connection with other layered materials.

In the example of FIG. 6, the method 600 includes an act 626 in which one or more additional device structures are formed. The device structure(s) may or may not be part of the heterostructure. For instance, the device structures may include additional layered materials of a conducting, semiconducting, or insulating nature. In other cases, one or more metal layers may be deposited and patterned to form one or more contacts or electrodes (e.g., source, drain, and gate electrodes).

The method 600 may include an act 628 in which the heterostructure is transferred from a growth substrate to another substrate (e.g., a device substrate). A wide variety of materials may be used for the device substrate, including, for instance, GaN, Si, sapphire. In other cases, an insulating substrate may be used, such as silicon dioxide.

The method 600 may include one or more additional acts. For instance, one or more acts may be configured or directed to forming additional structures of the device before or after transfer of the heterostructure to a device substrate. The additional structures may be supported by the device substrate. For instance, a gate electrode may be formed on an opposite side of the device substrate.

The method 600 may include fewer, alternative, or additional acts. For example, the method 600 may not include the transfer of the heterostructure in the act 628.

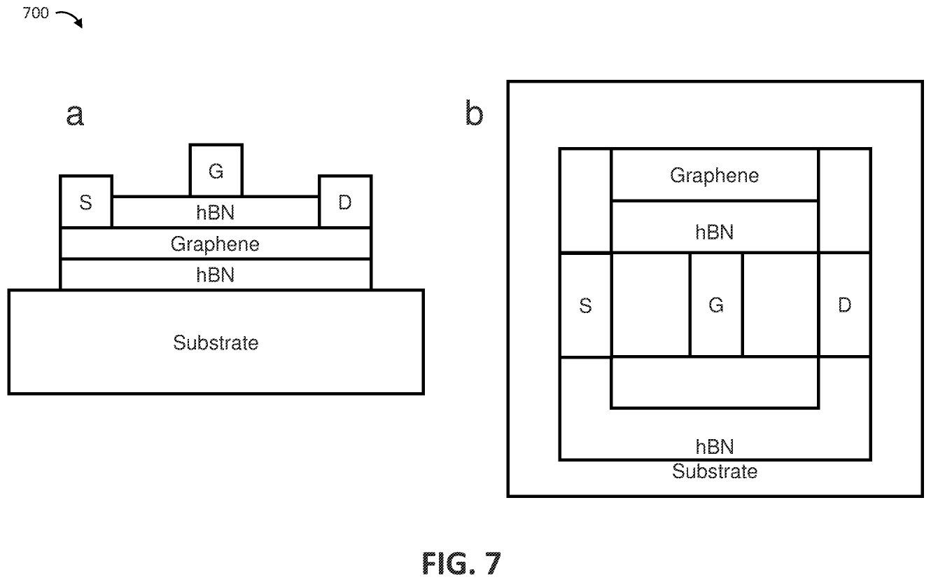

FIG. 7 depicts a device 700 having a heterostructure with a nanoribbon or other nanostructure in accordance with one example. The device 700 may be fabricated via the method 600 of FIG. 6 and/or another method. In this example, the device 700 is configured as a transistor device.

The device includes a substrate and a heterostructure supported by the substrate. As described above, the heterostructure includes a layered material structure supported by the substrate, and a nanostructure disposed laterally adjacent to the layered material structure to define an interface between the layered material structure and the nanostructure. In the example of FIG. 7, the layered material structure may be located behind the nanostructure as shown in the plan view. The nanoribbon may be composed of, or include, hBN, as shown, but additional or alternative layered materials may be used.

As described herein, the nanostructure has an edge opposite the interface between the layered material structure and the nanostructure that has a single atomic configuration.

The device 700 further includes a drain electrode, a source electrode spaced from the drain electrode, and a gate electrode disposed between the drain and source electrodes. In this case, the heterostructure further includes a semiconductor layer on which the nanoribbon is disposed, and an insulator layer on which the semiconductor layer is disposed. In this example, the semiconductor layer is composed of, or includes, graphene. The insulator layer is composed of, or includes, hBN, but additional or alternative insulator materials may be used.

As shown in FIG. 7, the nanostructure is disposed in a stacked arrangement between the gate electrode and the semiconductor layer to act as a dielectric layer for the gate electrode.

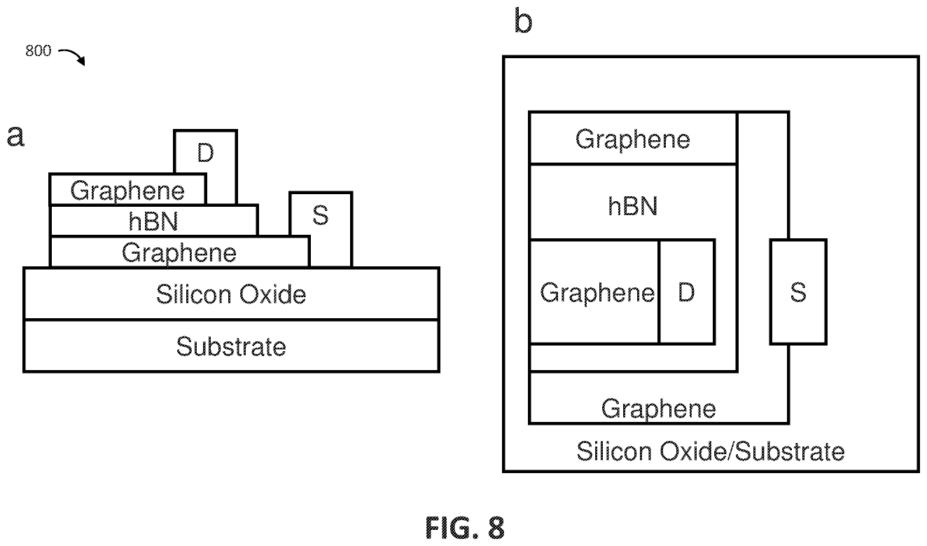

FIG. 8 depicts another device 800 having a heterostructure with a nanoribbon or other nanostructure in accordance with one example. The device 800 may be fabricated via the method 600 of FIG. 6 and/or another method. In this example, the device 800 may be configured as a tunneling junction device.

The hBN layer grows from one graphene atomic edge located behind the hBN layer. Thus, in this example, the hBN layer is grown from another graphene edge behind the hBN layer. As shown in the plan view, in this example, the graphene atomic edge is located behind the hBN layer.

In the device 800, the bottom and top graphene layers may act as an emitter and a collector, respectively. The hBN layer acts as a tunneling layer.

The device 800 includes a heterostructure stack of alternating layers. In this example, the stack includes alternating layers (or structures) of hBN and graphene. Thus, two layers of graphene are spaced apart by the hBN nanostructure.

In operation, a voltage applied between a backside gate electrode and the lower graphene layer can drive electrons from the lower graphene layer to the upper graphene layer. The electrons can move through the hBN nanostructure via quantum tunneling. Such charge movement may be used to support emission at a desired wavelength.

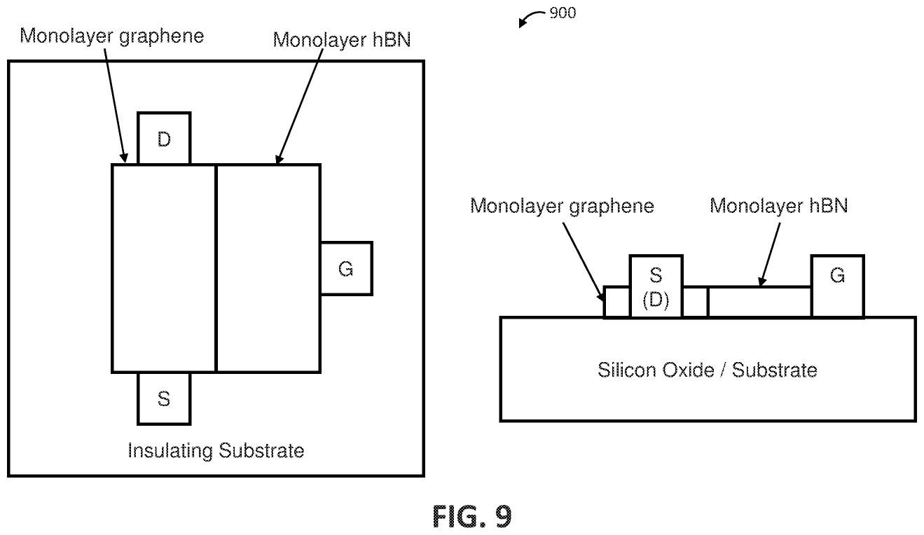

FIG. 9 depicts a device 900 having a heterostructure with a nanoribbon or other nanostructure in accordance with one example. The device 900 may be fabricated via the method 600 of FIG. 6 and/or another method. In this example, the device 900 may be configured as a monolayer lateral transistor.

The device includes a substrate and a heterostructure supported by the substrate. As described above, the heterostructure includes a layered material structure supported by the substrate, and a nanostructure disposed laterally adjacent to the layered material structure to define an interface between the layered material structure and the nanoribbon. In this example, the layered material structure is composed of, or includes, graphene. The graphene is configured to act as a semiconductor channel of the device 900, as described below.

The nanostructure is composed of, or includes, a layered material. In this example, the layered material is or includes monolayer hBN. The nanostructure acts as a gate dielectric of the device 900, as described below.

The substrate may be composed of, or otherwise include, an insulating material. In this example, the heterostructure is in contact with the substrate. In other cases, one or more layers are disposed between the substrate and the heterostructure.

As shown in FIG. 9, the interface between the layered material structure (graphene) and the nanoribbon has a unidirectional atomic boundary. The nanostructure has an edge opposite the interface that also has a single atomic configuration and, thus, in this case, a unidirectional atomic boundary. As described above, the interface has an armchair-armchair atomic configuration. Thus, the unidirectional atomic boundaries are arranged such that the edge is straight. As a result, the gate dielectric provided by the nanoribbon has a uniform width.

The nanostructure may be configured as a monolayer of the layered material. As a gate dielectric, the nanostructure may be relatively narrow. For example, the nanostructure may have a width falling in a range of about 50 nm to about 100 nm, but the dimensions of the nanostructure may vary.

The device 900 further includes a drain electrode, a source electrode spaced from the drain electrode, and a gate electrode disposed between the drain and source electrodes. The nanoribbon is disposed between the gate electrode and the layered material structure to act as a gate dielectric of a lateral transistor arrangement. The layered material structure is disposed between the drain and source electrodes in accordance with the lateral transistor arrangement. In that arrangement, a bias voltage applied to the gate electrode leads to pinch off (or formation) of a channel in the layered material structure to forbid (or allow) charge carriers to flow between the source and drain electrodes.

The source, drain, and gate electrodes may be composed of, or otherwise include, one or more metals. For instance, one or more of the electrodes may include a titanium layer and a gold layer.

In the example of FIG. 9, the heterostructure is in contact with the substrate. In other cases, one or more intermediate layers may be present. The device 900 may include any number of additional layers or structures.

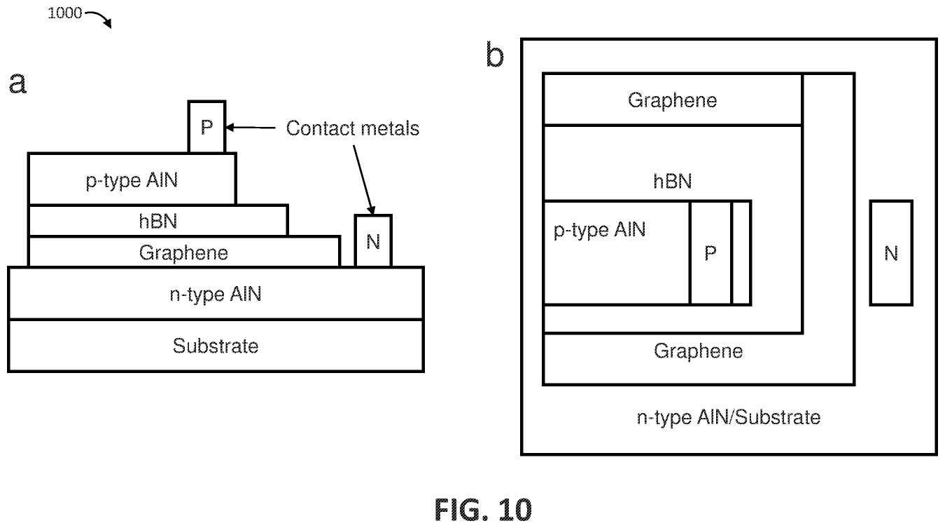

FIG. 10 depicts a device 1000 that exhibits the giant bandgap renormalization effect of hBN sitting on graphene layers. The device 1000 may be configured as a hBN-based deep ultraviolet light emitting device.

In this example, the device 1000 includes a composite substrate. The substrate may include a surface of metal or semi-metal, such as graphene. In this case, the device 1000 includes a substrate having a layered material surface (e.g., a graphene surface). In this case, the substrate includes a graphene layer that establishes the layered material surface.

The device includes a nanostructure. In this case, the nanostructure is composed of hexagonal boron nitride. The nanostructure is disposed on, and is in contact with, the substrate surface to form a stacked heterostructure.

As described herein, the stacked heterostructure may have a bandgap lower than a bandgap of hexagonal boron nitride. The stacked heterostructure may accordingly exhibit photoluminescence

In some cases, the device 1000 may be configured such that the disposition of the nanostructure on, and in contact with, the layered material surface of the substrate forms a moiré superlattice, as described herein.

In the example of FIG. 10, graphene layers are disposed on a n-type wide bandgap semiconductor, such as n-AlN or its alloy n-AlGaN. The n-type wide bandgap semiconductor acts as the electron injection layer. Layered hBN grown along the graphene atomic edges is disposed on the graphene layers and acts as the active region of the light emitting device. A p-type wide bandgap semiconductor, such as p-AlN or its alloy p-AlGaN, is disposed on an epitaxially grown hBN layer and acts as the hole injection layer. Metals, such as nickel, titanium, and gold, may also be disposed on the n-AlN semiconductor and p-AlN semiconductor, respectively, to act as ohmic contacts.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A method of fabricating a heterostructure, the method comprising:
forming a layered material structure such that the layered material structure has an edge; and
growing epitaxially a nanostructure of layered material laterally from the edge of the layered material structure such that an in-plane interface between the layered material structure and the nanostructure is defined;
wherein growing the nanostructure is implemented at a growth temperature sufficiently near a decomposition temperature of the layered material such that a nucleation interface of the nanostructure has a single atomic configuration.

2. The method of claim 1, wherein the growth temperature is closer to the decomposition temperature than to a threshold temperature at which growth of the layered material occurs.

3. The method of claim 1, wherein:
the layered material comprises hexagonal boron nitride; and
the growth temperature is at or above 1600 degrees Celsius.

4. The method of claim 1, wherein:
the layered material comprises hexagonal boron nitride; and
the layered material structure comprises graphene.

5. The method of claim 1, wherein growing the nanostructure comprises growing a monolayer of the layered material.

6. The method of claim 1, wherein the single atomic configuration is an armchair||armchair atomic configuration.

7. The method of claim 1, wherein the single atomic configuration establishes that a growth front of the nanostructure is unidirectional.

8. The method of claim 1, wherein the layered material structure comprises graphene.

9. The method of claim 1, wherein forming the layered material structure comprises exfoliating a substrate that supports the layered material structure to define the layered material structure and the unidirectional atomic edge.

10. The method of claim 1, wherein forming the layered material structure comprises:
depositing layered material across a substrate such that the layered material is supported by the substrate; and
patterning the deposited layered material to define the layered material structure.

11. The method of claim 1, further comprising providing a substrate that supports the layered material structure, the substrate comprising graphite.

12. The method of claim 1, wherein forming the layered material structure comprises implementing a photolithography procedure to define the unidirectional atomic edge.

13. The method of claim 1, wherein growing the nanostructure comprises growing a nanoribbon of the layered material.

14. The method of claim 1, wherein forming the layered material structure comprises forming a plurality of defects in a surface of the layered material structure.

15. A device comprising:
a substrate; and
a heterostructure supported by the substrate, the heterostructure comprising:
a layered material structure supported by the substrate; and
a nanostructure disposed laterally adjacent to the layered material structure to define an interface between the layered material structure and the nanostructure, the nanostructure comprising a layered material;
wherein an edge of the nanostructure opposite the interface has a single atomic configuration.

16. The device of claim 15, wherein the single atomic configuration establishes that the edge is unidirectional.

17. The device of claim 15, wherein the interface has an armchair||armchair atomic configuration.

18. The device of claim 15, wherein the nanostructure is a monolayer of the layered material.

19. The device of claim 15, wherein the layered material comprises hexagonal boron nitride.

20. The device of claim 15, wherein the layered material structure comprises graphene.

21. The device of claim 15, wherein the substrate comprises an insulating material.

22. The device of claim 15, further comprising a drain electrode, a source electrode spaced from the drain electrode, and a gate electrode disposed between the drain and source electrodes, wherein:
the nanostructure is disposed between the gate electrode and the layered material structure to act as a gate dielectric of a lateral transistor arrangement; and
the layered material structure is disposed between the drain and source electrodes in accordance with the lateral transistor arrangement.

23. The device of claim 15, further comprising a drain electrode, a source electrode spaced from the drain electrode, and a gate electrode disposed between the drain and source electrodes, wherein:
the heterostructure further comprises a semiconductor layer on which the nanostructure is disposed, and an insulator layer on which the semiconductor layer is disposed; and
the nanostructure is disposed in a stacked arrangement between the gate electrode and the semiconductor layer to act as a dielectric layer for the gate electrode.

24. The device of claim 15, further comprising a heterostructure stack comprising first and second structures spaced apart by the nanostructure.

25. The device of claim 15, wherein the nanostructure comprises a nanoribbon.

26. A device comprising:
a substrate; and
a heterostructure supported by the substrate, the heterostructure comprising:
a layered material structure supported by the substrate; and
a nanostructure disposed laterally adjacent to the layered material structure to define an interface between the layered material structure and the nanostructure, the nanostructure comprising a layered material;
wherein:
an edge of the nanostructure opposite the interface has a single atomic configuration;
the substrate comprises a layered material surface; and
the nanostructure is disposed on, and is in contact with, the layered material surface of the substrate to form a moiré superlattice.

27. A device comprising:
a substrate; and
a heterostructure supported by the substrate, the heterostructure comprising:
a layered material structure supported by the substrate; and
a nanostructure disposed laterally adjacent to the layered material structure to define an interface between the layered material structure and the nanostructure, the nanostructure comprising a layered material;
wherein:
an edge of the nanostructure opposite the interface has a single atomic configuration;
the substrate comprises a surface of metal or semi-metal;
the nanostructure comprises hexagonal boron nitride;
the nanostructure is disposed on, and is in contact with, the surface to form a stacked heterostructure; and
the stacked heterostructure has a bandgap lower than a bandgap of hexagonal boron nitride.

28. A device comprising:
a substrate; and
a heterostructure supported by the substrate, the heterostructure comprising:
a layered material structure supported by the substrate; and
a nanostructure disposed laterally adjacent to the layered material structure to define an interface between the layered material structure and the nanostructure, the nanostructure comprising a layered material;
wherein:
an edge of the nanostructure opposite the interface has a single atomic configuration;
the substrate comprises a graphene surface; and
the nanostructure comprises hexagonal boron nitride; and
the nanostructure is disposed on, and is in contact with, the graphene surface to form a stacked heterostructure; and
the stacked heterostructure exhibits photoluminescence.
